(19) United States
(12) Patent Application Publication
(10) Pub. No.: US 2010/0214462 A1
(43) Pub. Date: Aug. 26, 2010

(54) SOLID-STATE IMAGE PICKUP DEVICE AND METHOD FOR DRIVING THE SAME

(76) Inventor: Keijirou Itakura, Osaka (JP)

Correspondence Address: MCDERMOTT WILL & EMERY LLP, 600 13TH STREET, NW, WASHINGTON, DC, 20005-3096, US

(21) Appl. No.: 12/599,906

(22) PCT Filed: Jan. 17, 2008
(86) PCT No.: PCT/JP2008/050501

§ 371 Date: Nov. 12, 2009

(30) Foreign Application Priority Data
May 28, 2007 (JP) 2007-140319

(51) Int. Cl. H04N 5/335

(52) U.S. Cl. 348/302; 348/E05.091

(57) ABSTRACT

A frame rate is improved in accordance with the number of times pixels are summed without increasing an operating frequency of a column scanning circuit, when pixel summation is performed between columns. According to the invention, a row scanner selectively controls unit pixels of a pixel array unit on a row-by-row basis. A column-by-column AD converter is provided in each of columns in the pixel array unit and converts an analog signal of each of the pixels in the rows selected by the row scanner into a digital signal. A column-by-column summer is provided in each of the columns and sums the digital signal of each of the pixels in the rows selected by the row scanner on a column-by-column basis. An input-output selector is provided between the column-by-column AD converters and the column-by-column summers, and selects the column-by-column AD converter of any arbitrary column as an input destination, while selecting the column-by-column summer of any arbitrary column as an output destination. A column scanner serially outputs summation results of the column-by-column summers by scanning columns. A controller controls the timing of the operations of the row scanner, the column-by-column AD converters, the input-output selector and the column-by-column summers.

### FIELD OF THE INVENTION

The present invention relates to a solid-state image pickup device comprising an AD converter in each column and a method of driving the solid-state image pickup device.

### BACKGROUND OF THE INVENTION

In recent years, a CMOS (Complementary Metal Oxide Semiconductor) image sensor comprising column-parallel ADCs (analog-digital converters), in which an AD converter is disposed in each column to de al with a matrix array of unit pixels, was launched as a solid-state image sensor. Examples of the conventional technology were disclosed in the following cited documents.

Patent Document 1 relates to a constitution wherein integral mode 8-bit AD converter elements, in which a generator of a ramp signal used as a stepwise wavy reference voltage necessary for AD conversion, a comparator and a register are used, are integrated on a column-by-column basis (for each column). This technology represents a basic structure where the AD converters are integrated on a column-by-column basis.

Non-Patent Document 1 recites a similar constitution wherein integral-mode AD converter elements, in which a ramp signal generator, a comparator, a counter and a memory are used, are integrated on a column-by-column basis (for each column). According to the technology, noises can be removed to reduce the variability generated in each column by executing subtracting processing between reference voltage data and signal voltage data written in the memory after the AD conversion.

In recent years, the number of pixels in a solid-state image pickup device has dramatically increased as the semiconductor miniaturizing technology is advancing. As the number of pixels increases, an amount of time for outputting all of pixel data increases. As a result, a frame rate decreases in an operation based on the same clock, which leads to a huge problem in an application which demands a moving image pickup mode. In a method disclosed so far to deal with the problem, the number of pixels is reduced through a pixel thinning process or an arithmetic addition of pixel data in the solid-state image pickup device so that the frame rate can be increased.

Patent Document 2 discloses a constitution wherein integral-mode AD converters, in which a ramp signal generator, a comparator, an up-down counter and a memory are used, are integrated on a column-by-column basis. In the constitution, the up-down counter is in charge of summing pixel signals in a high-speed frame rate mode.

FIG. 17 illustrates a conventional solid-state image pickup device B recited in the Patent Document 2. Referring to reference numerals illustrated in FIG. 17, 10 denotes a pixel array unit in which unit pixels 12 including photoelectric conversion elements are two-dimensionally disposed in a matrix array, 14 denotes a row selecting line, 16 denotes a column signal line, 18 denotes a row scanning circuit, and 24 denotes a column processor comprising an array of AD converters 29 provided column by column. The AD converter 29 comprises a comparator 25, an up-down counter 26, a transfer switch 27 and a memory 28. 31 denotes a horizontal output line from the memory cell 28 in an odd-numbered column, while 32 denotes a horizontal output line from the memory cell 28 in an even-numbered column. 50 denotes a column scanning circuit, 60 denotes a timing control circuit, 61 denotes a reference voltage supplier comprising a DA converter 62, and 71 denotes a digital summer.

Referring to the unit pixels 12 disposed in the two-dimensional matrix array in the pixel array unit 10, a group of unit pixels 12 for one row are connected to the row scanning circuit 18 by way of the row selecting line 14, while a group of unit pixels 12 for one column are connected to an input terminal of the AD converter 29 provided column by column by way of the column signal line 16.

Next, an operation is described. AD conversion is carried out by the comparator 25 and the up-down counter 26 operating cooperatively with each other. A reference voltage Vref having a ramp waveform is supplied to the comparator 25 from the DA converter 62. The comparator 25 compares a signal voltage Vx outputted from each of the unit pixels 12 by way of the column signal line 16 to the reference voltage Vref having the ramp waveform, and inverts an output Vco when the two voltages are equal. At the time of this reading operation for the first row, the up-down counter 26 counts clocks to thereby measure a comparison time of the comparator 25. The transfer switch 27 remains OFF. At the time of this reading operation for the second row, the up-down counter 26 counts clocks to thereby measure the comparison time of the comparator 25. Through these processes, pixels between the two rows are summed in the up-down counter 26. After the AD conversion is completed, a digital value is retained in the up-down counter 26. Then, the transfer switch 27 is controlled by the timing control circuit 60, and a counting result of the up-down counter 26 is transferred to the memory cell 28. Through column scanning by the column scanning circuit 50, the data stored in the memory cells 28 is serially read in the order of odd-numbered column→even-numbered column→odd-numbered column→even-numbered column, and the digital summer 71 then sums the read data in an odd-numbered column and an even-numbered column. In other words, the pixel data in the two columns and two rows are summed. As the summation is repeatedly executed, the pixel data thinned by ½ in vertical and horizontal directions is generated.

As described, in the solid-state image pickup device B, the counting operation by the up-down counter 26 is continuously executed with regard to the pixel signals in different rows, so that the pixels between different rows (an odd-numbered column and an even-numbered column) are summed. Further, the data of the memory cells 28 is column scanned and inputted to the digital summer 71, so that the pixels between different columns are summed.
Patent Document 1: Japanese Patent No. 2532374 (Pages 3-8, FIGS. 1-5)
Patent Document 2: 2005-278135 of the Japanese Patent publications Laid-Open (Pages 14-15, FIG. 8)
Non-Patent Document 1: W. Yang et al, “An Integrated 800×600 CMOS Image System” ISSCCDigeat of Technical Papers, Page 304-305, February, 1999

### DISCLOSURE OF THE INVENTION

### Problem to be Solved by the Invention

According to the Patent Document 2, AD conversion time per pixel is shortened in accordance with the number of the pixels to be summed, and the frame rate can be thereby improved in accordance with the number of the pixels to be summed. According to the Patent Document 2, wherein the digital summer 71 behind the column scanning circuit 50 is in charge of the pixel summation between the different columns, however, it is necessary to increase an operation frequency as the number of the columns subject to the pixel summation is increased. This indicates that the frame rate cannot be improved if it is not possible to increase the operation frequency of the column scanning circuit 50, or the number of the column scanning circuits 50 has to be increased if the same operation frequency is used. However, either case may cause a problem, which is the increase of a circuit area or the deterioration of an image quality resulting from the variability generated between two or more column scanning circuits 50. Further, in the case where the pixels are summed, the AD conversion time needs to be shortened in accordance with the number of the pixels to be summed, which results in the deterioration of a bit accuracy in the AD conversion. It should be noted that the Patent Document 1 and the Non-Patent Document 1 do not include any description relating to the pixel summation for improving a frame rate and sensitivity.

The present invention was made in view of the foregoing problems, and a main object thereof is to improve a frame rate in accordance with the number of the pixels to be summed without increasing the operation frequency of a column scanning circuit in the case where the pixels are summed between columns, and to improve sensitivity in accordance with the number of the pixels to be summed by maintaining the same AD conversion time per pixel, in other words, by maintaining the bit accuracy in the AD conversion when the pixels are summed.

### Means for Solving the Problem

1) A solid-state image pickup device according to the present invention comprises:

a pixel array unit in which unit pixels including photoelectric conversion elements are two-dimensionally disposed in a matrix array;

a row scanner for selectively controlling the unit pixels of the pixel array unit on a row-by-row bais;

column-by-column AD converters provided in columns of the pixel array unit on a column-by-column basis for converting an analog signal of each pixel in the row selected by the row scanner into a digital signal;

column-by-column summers provided in the columns on a column-by-column basis for summing the digital signal of each pixel in the row selected by the row scanner on a column-by-column basis;

an input/output selector provided between the column-by-column AD converters and the column-by-column summers, the input/output selector selecting the column-by-column AD converter in any arbitrary column as an input destination and further selecting the column-by-column summer in any arbitrary column as an output destination;

a column scanner for serially outputting summation results of the column-by-column summers by scanning columns; and

a controller for controlling the timing of the operations of the row scanner, the column-by-column AD converters, the input/output selector and the column-by-column summers.

The solid-state image pickup device thus constituted is characterized in that the column-by-column summers, each of which is provided in each column, are provided, and the input/output selector for controlling the combination of the input and output is provided between a plurality of the column-by-column summers and a plurality of the column-by-column AD converters.

A method of driving a solid-state image pickup device corresponding to the solid-state image pickup device recited in 1) comprises:

a first step in which a selected row is set in a pixel array unit in which unit pixels including photoelectric conversion elements are two-dimensionally disposed in a matrix array, and analog signals of the unit pixels in each column of the selected row are AD-converted so as to generate a group of selected-row digital signals;

a second step in which a first selected column is set in the pixel array unit, and the selected-row digital signal in the first selected column (first selected column) is retrieved from the group of selected-row digital signals and retained;

a third step in which a second selected column is set in the pixel array unit, and the selected-row digital signal in the second selected column (second selected column) is retrieved from the group of selected-row digital signals and added to the selected-row digital signal (first selected column) so as to generate a summation digital signal (first selected column+second selected column);

a fourth step in which the first-third steps are carried out by changing the selected row so as to serially generate a group of the summation digital signals for a plurality of rows (first selected column+second selected column); and

a fifth step in which the summation digital signals (first selected column+second selected column) constituting the group of the summation digital signals of the plurality of rows (first selected column+second selected column) are serially outputted by column scanning.

In the constitution described above, the row scanner sets any arbitrary row as a selected row in the pixel array unit, and the column-by-column AD converter converts the analog signals from a group of pixels in the selected row into the digital signals and then sends the digital signals to the input/output selector. The input/output selector selects the outputs of the column-by-column AD converters corresponding to the pixels to be summed in the column direction [selected-row digital signal (first selected column), selected-row digital signal (second selected column)], and outputs the selected digital signals to the column-by-column summer. There are more than one column-by-column summer, and each of the column-by-column summers sums the digital signals supplied from the plurality of column-by-column AD converters [selected-row digital signal (first selected column), selected-row digital signal (second selected column)] and thereby generates the summation digital signal (first selected column+second selected column). The summation digital signal (first selected column+second selected column) obtained from the summation is temporarily retained in the column-by-column summer. Then, the row scanner selects another row, and the column-by-column AD converter converts the analog signals from the group of the pixels in the selected row into digital signals and sends them to the input/output selector. The input/output selector selects the output digital signals of the column-by-column AD converters corresponding to the pixels to be summed [(selected-row digital signal (first selected column), selected-row digital signal (second selected column)], and sends the selected digital signals to the column-by-column summer which is different to the before-mentioned column-by-column summer. Each of the column-by-column summers sums the digital signals supplied from the plurality of column-by-column AD converters [(selected-row digital signal (first selected column), selected-row digital signal (second selected column)]. The summation digital signal obtained from the summation (first selected column+second selected column) is also temporarily retained in the column-by-column summer which is referred to above as another summer. Thus processed, composite pixel summation data, in which intra-row pixel summation data is incorporated between a plurality of rows, is generated. Then, the column scanner serially outputs the summation result in each of the column-by-column summers.

A description is further given below referring to an example so as to facilitate the understanding of the present invention. In the first row of the pixel array unit, for example, the pixel data of the first pixel (pixel in the first column) and the pixel data of the second pixel (pixel in the second column) are summed by the column-by-column summer in the first column, the pixel data of the third pixel and the pixel data of the fourth pixel are summed by the column-by-column summer in the third column, and thereafter, the pixel data of the (2n−1)th pixel and the pixel data of the 2nth pixel are summed by the column-by-column summer in the (2n−1)th column (n is a natural number equal or larger than 2). In other words, the pixel data of the two pixels adjacent to each other are summed by the column-by-column summer in the odd-numbered column. Then, in the second row of the pixel array unit, the pixel data of the first pixel and the pixel data of the second pixel are summed by the column-by-column summer in the second column, the pixel data of the third pixel and the pixel data of the fourth pixel are summed by the column-by-column summer in the fourth column, and thereafter, the pixel data of the (2n−1)th pixel and the pixel data of the 2nth pixel are summed by the column-by-column summer in the 2nth column. In other words, the pixel data of the two pixels adjacent to each other are summed by the column-by-column summer in the even-numbered column. As a result, the summation data of the two adjacent pixels in the first row, the summation data of the two adjacent pixels in the second row, the summation data of the two adjacent pixels in the first row, the summation data of the two adjacent pixels in the second row, . . . , are retained in the plurality of column-by-column summers. This is composite pixel summation data in which the intra-row pixel summation data is incorporated between a plurality of rows, and these two-pixel summation data are serially outputted by column scanning. Thus, the pixel summation in the column direction and the pixel summation in the row direction are effectively combined.

In the case of the conventional technology, improvement in the processing speed of the column scan is limited because the pixel summation between columns is carried out on the output side of the column scanning circuit. According to the present invention, however, the pixels are summed on the input side of the column scanning circuit. Therefore, it is unnecessary to increase the operation frequency of the column scanning circuit and to increase the number of the column scanners in order to effectively perform the summation in the column and row directions. As a result, the frame rate can be improved.

2) The solid-state image pickup device recited in 1) may further comprise a line memory for temporarily storing the summation results of the column-by-column summers between the plurality of column-by-column summers and the column scanner. A method of driving the solid-state image pickup device thus constituted further includes a sixth step in which the group of the summation digital signals (first selected column+second selected column) are temporarily stored, between the fourth step and the fifth step.

According to the constitution, since the line memory is provided between the plurality of the column-by-column summers and the column scanner, only if one cycle of the summing process is completed in all of the column-by-column summers in the pixel rows subject to the summation, the row selection for a subsequent cycle can be immediately started by the row scanner. Therefore, it is unnecessary to wait for one cycle of the column scan to be completed before the row selection for the subsequent cycle is started by the row scanner. The row selection for the subsequent cycle can be started the column scan cycle is started right after the data in all of the column-by-column summers is stored in the line memory, and the operation can then proceed to the column-by column AD conversion, input/output selection, and the column-by-column summation. Therefore, the column scan and other processes such as the column-by-column AD conversion, input/output selection and column-by-column summation can be concurrently carried out. As a result, the frame rate can be further improved.

3) The solid-state image pickup device constituted as described above may further comprise:

a memory cell array unit in which output data of the column-by-column AD converters for a plurality of rows can be written on a row-by-row basis and from which the data can be read with respect to the column-by-column summers on a row-by-row basis; and

a memory row selector for controlling the data write and the data read of the memory cell array unit by selecting rows.

A method of driving the solid-state image pickup device thus constituted further includes a seventh step and an eighth step between the first step and the second step, wherein

in the seventh step, the group of selected-row digital signals generated in the first step are retained;

in the eighth step, the first and seventh steps are carried out by changing the selected row and a group of the selected-row digital signals for a plurality of rows are thereby generated and retained, and

in the second step, a group of selected-row digital signals of any arbitrary row is read from among the group of selected-row digital signals for the plurality of rows retained in the eighth step and used.

In the case where the solid-state image pickup device is thus constituted, the row selection for the next cycle can be immediately started by the row scanner only if one cycle of the AD conversion of all of the pixels by the column-by-column converters and the data write with respect to the memory cells is completed concerning a plurality of pixel rows subject to summation because the memory cell array unit is provided between the column-by-column AD converters and the input/output selector. In other words, it is not necessary to wait for a cycles of the input/output selection and the column-by-column summation to be completed before the row selection for the next cycle is started by the row scanner. Therefore, the row selection for the next cycle can be started immediately before or after a cycle of the input/output selection and the column-by-column summation is started right after the AD conversion with respect to all of the pixels is completed, and the operation can proceed to column-by-column AD conversion. As a result, the column scan and other processes such as the column-by-column AD conversion, input/output selection and column-by-column summation can be concurrently carried out, and the frame rate can be thereby further improved.

### EFFECT OF THE INVENTION

According to the present invention,
the column-by-column summers are provided on a column-by-column basis; and
the input/output selector for controlling the combination of the input and output is provided between the column-by-column summers and the column-by-column AD converters.

As a result, the pixels can be effectively summed in the row and column directions without any increase of the operation frequency of the row scanner when the pixels are summed between the columns, and the frame rate can be thereby improved.

According to the present invention,
the line memory, which is an array of memory cells corresponding to the column-by-column summers, is provided; and
a memory cell array unit for a plurality of rows corresponding to the column-by-column AD converters is provided.

As a result, each process can be concurrently carried out, so that a pipeline operation is materialized, and the frame rate can be thereby further improved.

### BRIEF DESCRIPTION OF THE DRAWINGS

FIG. 1 is a block diagram illustrating a constitution of a solid-state image pickup device (basic structure) according to a preferred embodiment 1 of the present invention.

FIG. 2 is a block diagram illustrating a constitution of the solid-state image pickup device of FIG. 1 illustrating the basic structure according to the preferred embodiment 1 adopted in the case where an input/output selecting circuit is adapted to two pixels only.

FIG. 3 is a timing chart illustrating an operation of the solid-state image pickup device having the structure illustrated in FIG. 2.

FIG. 4 is an operation transition chart (1) in the solid-state image pickup device according to the preferred embodiment 1.

FIG. 5 is an operation transition chart (2) in the solid-state image pickup device according to the preferred embodiment 1.

FIG. 6A is a drawing (1) abstractly illustrating a state transition to additionally describe the operation according to the preferred embodiment 1.

FIG. 6B is a drawing (2) abstractly illustrating a state transition to additionally describe the operation according to the preferred embodiment 1.

FIG. 6C is a drawing (3) abstractly illustrating a state transition to additionally describe the operation according to the preferred embodiment 1.

FIG. 7 is a block diagram illustrating a constitution of a solid-state image pickup device (basic structure) according to a preferred embodiment 2 of the present invention.

FIG. 8 is a block diagram illustrating a constitution of the solid-state image pickup device of FIG. 7 illustrating the basic structure according to the preferred embodiment 2 adopted in the case where an input/output selecting circuit is adapted to two pixels only.

FIG. 9 is a timing chart illustrating an operation of the solid-state image pickup device having the structure illustrated in FIG. 8.

FIG. 10 is an operation transition chart (1) in the solid-state image pickup device according to the preferred embodiment 2.

FIG. 11 is an operation transition chart (2) in the solid-state image pickup device according to the preferred embodiment 2.

FIG. 12 is a block diagram illustrating a constitution of a solid-state image pickup device (basic structure) according to a preferred embodiment 3 of the present invention.

FIG. 13 is a block diagram illustrating a constitution of the solid-state image pickup device of FIG. 12 illustrating the basic structure according to the preferred embodiment 3 adopted in the case where an input/output selecting circuit is adapted to two pixels only.

FIG. 14 is a timing chart illustrating an operation of the solid-state image pickup device having the structure illustrated in FIG. 13.

FIG. 15 is an operation transition chart (1) in the solid-state image pickup device according to the preferred embodiment 3.

FIG. 16 is an operation transition chart (2) in the solid-state image pickup device according to the preferred embodiment 3.

FIG. 17 is a block diagram illustrating a constitution of a solid-state image pickup device according to conventional technology.

### DESCRIPTION OF REFERENCE SYMBOLS

A solid-state image pickup device (CMOS image sensor)
10 pixel array unit
12 unit pixel
14 row selecting line
16 column signal line
18 row scanning circuit
20 column AD converting unit
22 column-by-column AD converter
30, 30a input/output selecting circuit
40 column summing unit
42 column-by-column summer
50 column scanning circuit
60 timing control circuit
70 line memory
72 memory cell
80 memory cell array unit
82 memory cell
85 row selecting circuit

### PREFERRED EMBODIMENTS OF THE PRESENT INVENTION

Hereinafter, preferred embodiments of a solid-state image pickup device according to the present invention are described in detail referring to the drawings.

### Preferred Embodiment 1

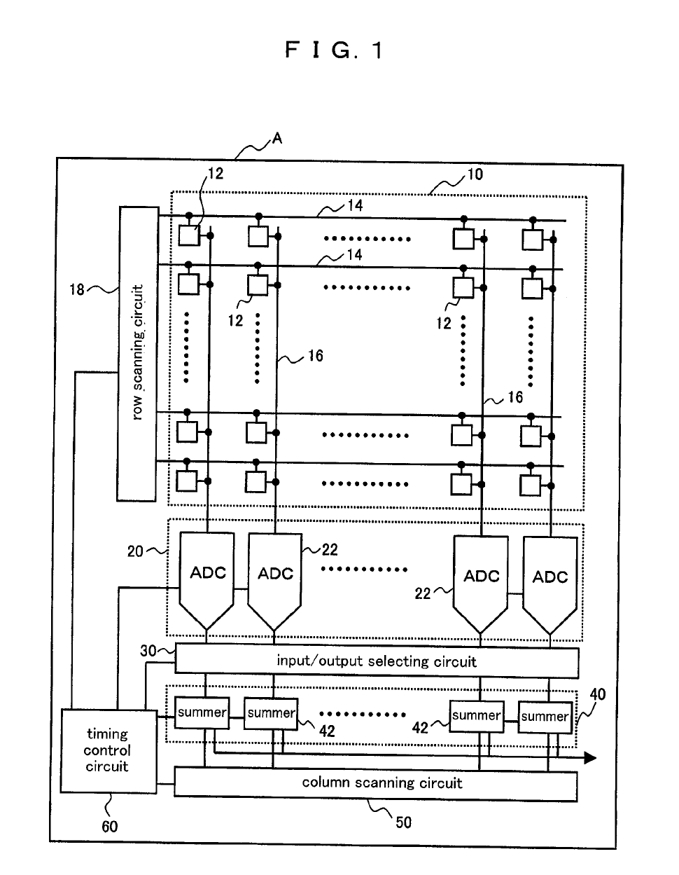

FIG. 1 is a block diagram illustrating a constitution of a solid-state image pickup device A according to a preferred embodiment 1 of the present invention. The solid-state image pickup device A is constituted as a CMOS image sensor provided with column-parallel ADCs.

Referring to reference numerals shown in FIG. 1, 10 denotes a pixel array unit in which unit pixels 12 including photoelectric conversion elements are two-dimensionally disposed in a matrix array, 14 denotes a row selecting line, 16 denotes a column signal line, 18 denotes a row scanning circuit, 20 denotes a column AD converting unit comprising an array of tow or more column-by-column AD converters 22, 30 denotes an input/output selecting circuit, 40 denotes a column summing unit comprising an array of column-by-column summers 42, 50 denotes a column scanning circuit, and 60 denotes a timing control circuit. With regard to the unit pixels 12 two-dimensionally disposed in the matrix array in the pixel array unit 10, a group of unit pixels 12 in one row are connected to the row scanning circuit 18 by way of the row selecting line 14, while a group of unit pixels in one column are connected to each input terminal of the column-by-column AD converters 22 in the column AD converting unit 20 by way of the column signal line 16.

Each of the column-by-column AD converters 22 in the column AD converting unit 20 is provided with the column-by-column summer 42. These two or more arrays of column-by-column summers 42 constitute the column summing unit 40. Each of the column-by-column AD converters 22 is provided in each of the columns of the two-dimensional matrix array of the unit pixels 12 in the pixel array unit 10. The AD converter 22 converts analog signals in the group of unit pixels 12 in the row selected by the row scanning circuit 18 by way of the row selecting line 14 into digital signals. More specifically, analog signals in each of the pixels provided column by column is converted into digital signals. Each of the column-by-column summers 42 is provided in each column of the two-dimensional matrix array of the unit pixels 12. The summer 42 sums the digital signals of the group of unit pixels 12 in the row selected by the row scanning circuit 18 on a column-by-column basis.

The input/output selecting circuit 30 is provided between the column AD converting unit 20 and the column summing unit 40. The input/output selecting circuit 30 comprises as many input ports as the number of the columns, and also comprises the same number of output ports as the input ports. The input/output selecting circuit 30 outputs the digital signal of any arbitrary one of the input ports to any arbitrary one of the output ports based on a control signal from the timing control circuit 60. More specifically, the input/output selecting circuit 30 selects one of the plurality of column-by-column AD converters 22 in any arbitrary column, as an input destination, and selects one of the plurality of column-by-column AD summers 42 in any arbitrary column, as an output destination. Each of the column-by-column summers 42 has a reset function and an enable function. These functions are controlled by the timing control circuit 60. Each of the column-by-column summers 42 has a function of increasing the number of digits at the time of the summation of a plurality of data in each of the column-by-column AD converters 22. The summer 42 is configured to be able to handle digits higher than the number of bits of the AD converter in accordance with the number of times summation is made. The column scanning circuit 50 scans the columns to thereby serially output summation results of the plurality of column-by-column summers 42 out of the device. The group of these column-by-column summers 42 retain therein composite pixel summation data in which intra-row summation data is incorporated between a plurality of rows. The timing control circuit 60 timing-controls the row scanning circuit 18, column converting unit 20, input/output selecting circuit 30, column summing unit 40, and column scanning circuit 50.

Each of the unit pixels 12 has a three-transistor configuration or a four-transistor configuration which is generally adopted. The unit pixel 12 may alternatively be configured such that a plurality of pixels having a plurality of transistors which share a photoelectric conversion unit constitute a unit cell.

The solid-state image pickup device A has two modes, which are a progressive operation mode for reading information of all of the unit pixels 12 and a pixel summation mode for summing pixels between column spaces different between tow or more rows, and the mode can be switched by changing a control signal from the timing control circuit 60. The mode is switched by inputting a signal from outside to the timing control circuit 60.

As an AD conversion method adopted in the column-by-column AD converter 22, the following methods can be considered: such a ramp run-up method that is recited in the Patent Document 2 wherein a comparator and a counter are provided and a ramp waveform (tilting waveform) is used as a reference potential; successive approximation method (for example, U.S. Pat. No. 5,880,691); cyclic method (for example, see the Japanese Patent Document (2006-25189 of the Japanese Patent Applications Laid-Open)); and ΔΣ modulation method (for example, see the Japanese Patent Document (2004-15208 of the Japanese Patent Applications Laid-Open)).

The preferred embodiment is specifically characterized in that the array of column-by-column summers 42 is provided on the input side of the column scanning circuit 50, and the input/output selecting circuit 30 capable of outputting a digital signal of any arbitrary input port to any arbitrary output port is interposed between the array of the column-by-column summers 42 and the array of the column-by-column AD converters 22.

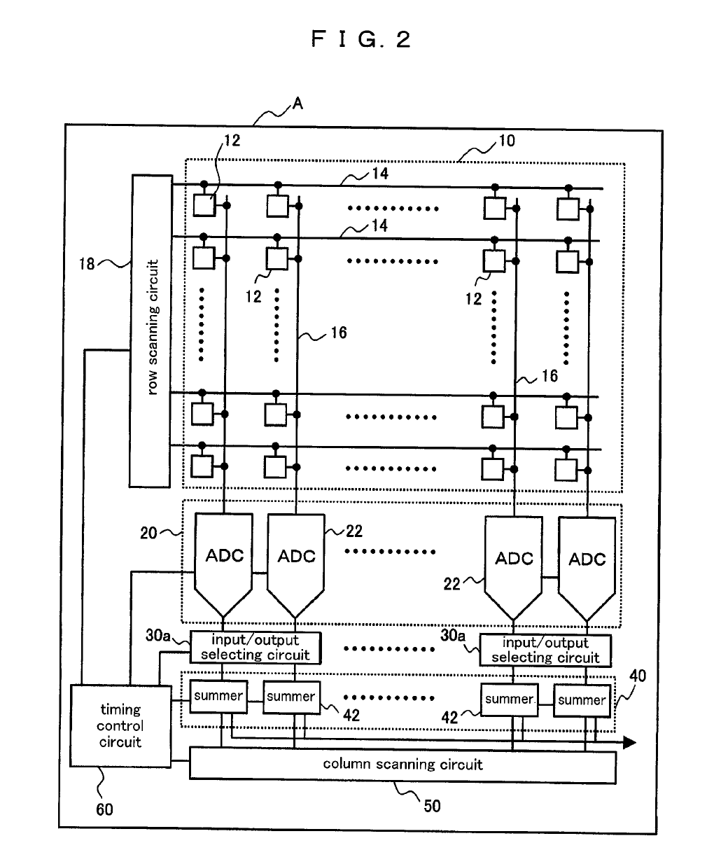

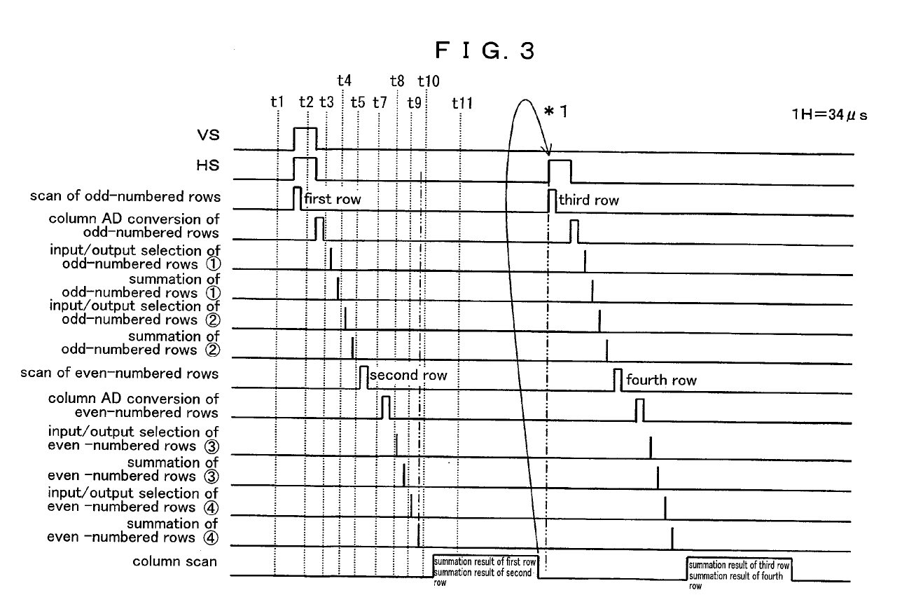

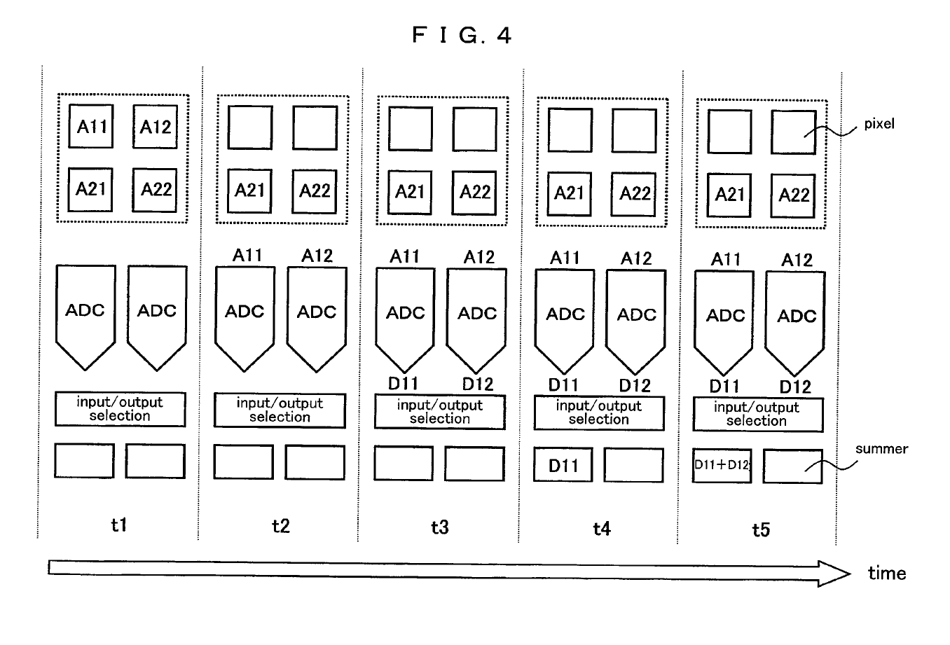

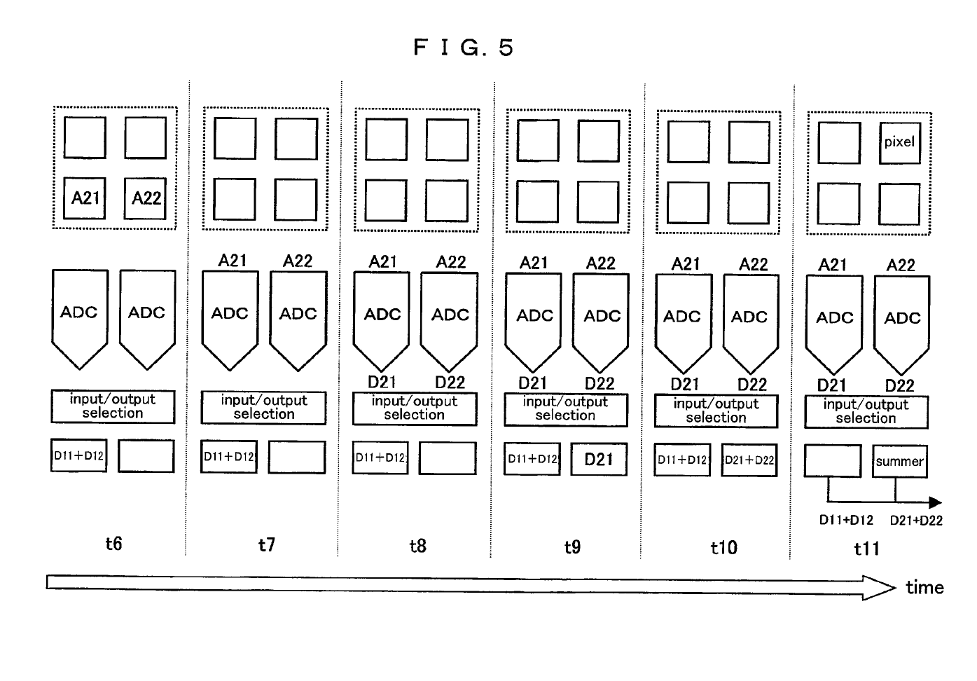

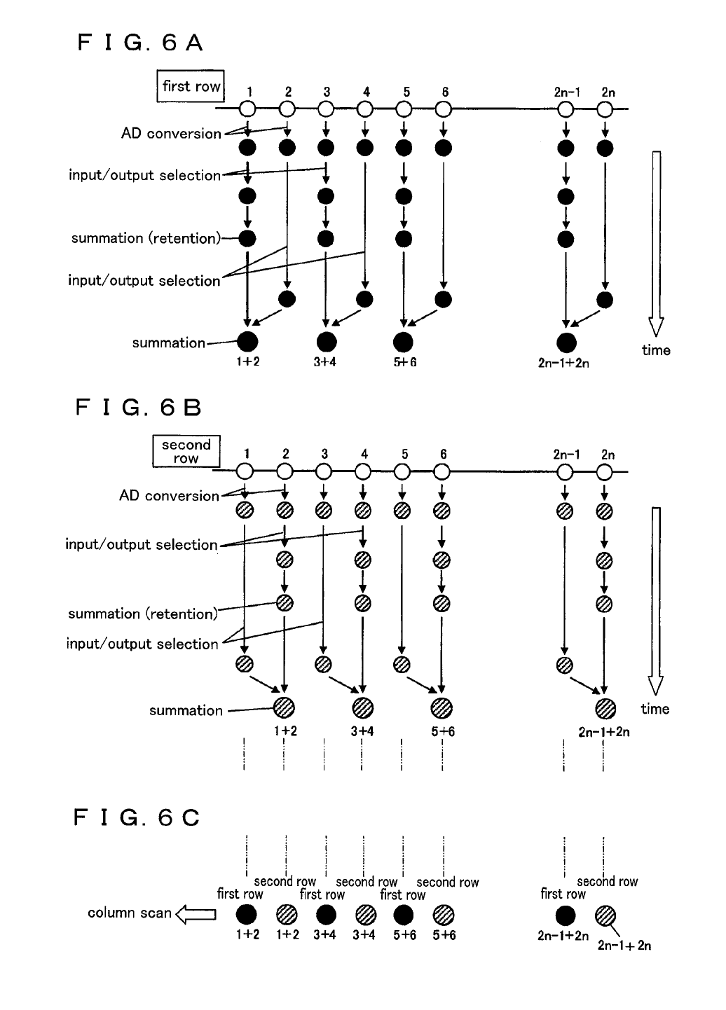

An operation of the solid-state image pickup device according to the present preferred embodiment thus constituted is described below. In the description given below relating to a driving method according to the present preferred embodiment, two pixels in the same row are summed so as to facilitate the understanding of the present invention. In this case, as illustrated in FIG. 2, a plurality of input/output selecting circuits 30a for selecting inputs and outputs in every two columns constitute the input/output selecting circuit 30. These input/output selecting circuits 30a have the same constitution and the same function. FIG. 3 is a timing chart illustrating an operation of the solid-state image pickup device A having the structure illustrated in FIG. 2. FIGS. 4 and 5 are timing charts illustrating the operation of the solid-state image pickup device according to the present preferred embodiment. FIGS. 6A-6C are drawings abstractly illustrating a state transition to additionally describe the operation. A longitudinal direction in FIGS. 6A-6C denotes a time axis.

First, an outline of the operation is described. A first row illustrated in FIG. 6A and a second row illustrated in FIG. 6B correspond to a first row and a second row illustrated in FIG. 3, respectively. In the description below, analog pixel values are converted into digital data and then summed. In FIG. 6, a white circle denotes an analog pixel value of each pixel, while a black circle denotes digital data.

Next, a more detailed description is given below referring to FIGS. 3 and 6A-6C. In FIG. 3, VS denotes a vertical synchronizing signal, while HS denotes a horizontal synchronizing signal. It is important to read the description given below while carefully paying attention to a distinction between “odd-numbered row,” “even-numbered row,” “odd-numbered column” and “even-numbered column.”

In the scan of the odd-numbered rows, the timing of selecting an odd-numbered row is illustrated. A pulse recited as the first row in the drawing shows a pulse outputted from the row scanning circuit 18 to the row selecting line 14 by its output timing in order to select the group of the unit pixels 12 in the first row in the pixel array unit 10. In the description of the operation below, an odd-numbered column is a first selected column, while an even-numbered column is a second selected column.

Column AD conversion timing in the scan of odd-numbered rows

This is the timing with which analog signals outputted from all of the unit pixels 12 in the selected row (odd-numbered row) are AD-converted into digital signals.

First input/output selection timing at the time of the generation of odd-numbered row/odd-numbered column data

This is the timing with which a selected-row digital signal (first selected column), which is a digital signal outputted from an AD converter 22 in an odd-numbered column, is selected and supplied to the summer 42 in the odd-numbered column.

Summation (retention) timing at the time of the generation of odd-numbered row/odd-numbered column data

This is the timing with which the selected-row digital signal (first selected column) inputted to the summer 42 in the odd-numbered column are summed (retained) by the same summer 42. Though not shown in the drawings, data in all of the column-by-column summers 42 are temporarily reset to “0” immediately before the timing described in this section arrives.

Second input/output selection timing at the time of the generation of odd-numbered row/odd-numbered column data

This is the timing with which a selected-row digital signal (second selected column), which is a digital signal outputted from the AD converter 22 in an even-numbered column, is selected and supplied to the summer 42 in the odd-numbered column.

Summation (retention) timing at the time of the generation of odd-numbered row/odd-numbered column data

This the timing with which, in the summer 42 in the odd-number column, the selected-row digital signal (second selected column) is added to the selected-row digital signal (first selected column) summed (retained) in the summer 42, so that an odd-numbered row summation digital signal (first selected column+second selected column) is generated.

Thus processed, the pixel data of two adjacent pixels in the same odd-numbered row are summed, and the resultant odd-numbered row summation digital signal (first selected column+second selected column) is retained in each of the multiple summers 42 in the odd-numbered columns (see FIG. 6A).

Next, the scan of an even-numbered row is described. In the scan of an even-numbered row, the timing of selecting an even-numbered row is illustrated. A pulse recited as the second row in the drawing shows a pulse outputted from the row scanning circuit 18 to the row selecting line 14 by its output timing in order to select the group of the unit pixels 12 in the second row in the pixel array unit 10. In the description given below, an odd-numbered column is a first selected column, while an even-numbered column is a second selected column.

Column AD conversion timing in the scan of an even-numbered row

This is the timing with which analog signals outputted from all of the unit pixels 12 in a selected row (even-numbered row) are AD-converted into digital signals.

First input/output selection timing at the time of the generation of the even-numbered row/even-numbered column data

This is the timing with which a selected-row digital signal (first selected column), which is a digital signal outputted from the AD converter 22 in an odd-numbered column, is selected and supplied to the summer 42 in an even-numbered column. The summers 42 in the odd-numbered columns, in which the summation results of the odd-numbered rows are already stored, can no longer be used for the summation.

Summation (retention) timing at the time of the generation of even-numbered row/even-numbered column data

This is the timing with which the selected-row digital signal (second selected column) inputted to the summer 42 in the even-numbered column are summed (retained) by the same summer 42.

Second input/output selection timing at the time of the generation of even-numbered row/even-numbered column data

This is the timing with which a selected-row digital signal (second selected column), which is a digital signal outputted from the AD converter 22 in an even-numbered column, is selected and supplied to the summer 42 in an even-numbered column.

Summation (retention) timing at the generation of even-numbered row/even-numbered column data

This the timing with which, in the summer 42 in an odd-numbered column, the selected-row digital signal (second selected column) is added to the selected-row digital signal (first selected column) summed (retained) in the same summer 42, so that an even-numbered row summation digital signal (first selected column+second selected column) is generated. The selected-row digital signal (even-numbered column) recited in this description denotes data outputted from the AD converter 22 in the even-numbered column to the summer 42 with the second input/output selection timing at the time of the generation of even-numbered row/even-numbered column data.

Thus processed, the pixel data of two adjacent pixels in the same even-numbered row are summed, and the resultant even-numbered row summation digital signal (first selected column+second selected column) is retained in each of the multiple summers 42 in the even-numbered columns (see FIG. 6B).

Next, the scan of columns is described. The odd-numbered row summation digital signals (first selected column+second selected column) which are the summation results of the even-numbered rows and the even-numbered row summation digital signals (first selected column+second selected column) which are the summation results of the even-numbered rows, both retained in the group of the column-by-column summers 42 through column scan, are serially outputted (see FIG. 6C). More specifically, data is serially outputted in the following order: (first pixel+second pixel) data which is the first odd-numbered row summation digital signal (first selected column+second selected column) in the first row→(first pixel+second pixel) data which is the first even-numbered row summation digital signal (first selected column+second selected column) in the second row→(third pixel+fourth pixel) data which is the second odd-numbered row summation digital signal (first selected column+second selected column) in the first row→(third pixel+fourth pixel) data which is the second even-numbered row summation digital signal (first selected column+second selected column) in the second row→(fifth pixel+sixth pixel) data which is the third odd-numbered row summation digital signal (first selected column+second selected column) in the first row→(fifth pixel+sixth pixel) data which is the third even-numbered row summation digital signal (first selected column+second selected column) in the second row. The whole pixel data constitutes composite pixel summation data in which the intra-row pixel summation data is incorporated between two or more rows. When the output of all of the summation data in the first row and the second row is completed, the summation data in the third row and the fourth row are processed (*1). The processing described so far is repeatedly executed, and consequently the pixel summation in the column direction (two columns) and the pixel summation in the row direction (two rows) are effectively combined.

The description of the operation was so far given referring to the abstract illustration (FIGS. 6A-6C) so that the present invention can be easily understood. Hereinafter, the operation is described based on its technical substance referring to operation transition charts illustrated in FIGS. 4 and 5. The reference symbols t1-t5 illustrated in FIG. 4 and t6-t11 illustrated in FIG. 5 denote serial numbers of timing. FIGS. 4 and 5 illustrate the operation for 2×2 pixels alone to facilitate the understanding.

In FIGS. 4 and 5, A11 denotes analog data of a pixel in the first row and first column, A12 denotes analog data of a pixel in the first row and second column, and A21 denotes analog data of a pixel in the second row and first column, and A22 denotes analog data of a pixel in the second row and second column. D11 denotes digital data obtained when the analog signal A11 is converted by the AD converter 22, D12 denotes digital data obtained when the analog signal A12 is converted by the AD converter 22, D21 denotes digital data obtained when the analog signal A21 is converted by the AD converter 22, and D22 denotes digital data obtained when the analog signal A22 is converted by the AD converter 22. t1-t11 denote the timings with which signals are processed, and more time has passed as the timing number is increased.

Timing t1

This is the timing with which charges, which represent a photoelectric conversion result of a photographic subject, are stored in the group of the unit pixels 12, and result in the analog data A11, A12, A21 and A22.

Timing t2

This is the timing with which the analog data A11 and A12 in the first row are inputted to the AD converters 22.

Timing t3

This is the timing with which the AD conversion of the analog data A11 and A12 by the AD converters 22 is completed, and the digital data D11 and D12 are outputted from the AD converters 22.

Timing t4

This is the timing with which the digital data D11 in the first row and first column is selected by the input/output selecting circuit 30, and the selected digital data D11 is outputted to the summer 42 provided in the first column.

Timing t5

This is the timing with which the digital data D12 in the first row and second column is selected by the input/output selecting circuit 30, and the selected digital data D12 is outputted to the summer 42 provided in the first column. In the summer 42, the digital data D12 outputted later is added to the digital data D11.

Timing t6

This is the timing with which the data of the AD converters are reset.

Timing t7

This the timing with which the analog data A21 and A22 in the second row are inputted to the AD converter 22.

Timing t8

This is the timing with which the AD conversion is completed, and the digital data D21 and D22 are outputted from the AD converters 22.

Timing t9

This is the timing with which the digital data D21 in the second row and first column is selected by the input/output selecting circuit 30, and the selected digital data D21 in the second row and first column is outputted to the summer 42 provided in the second column, so that summation result data (D21+D22) is generated.

Timing t10

This is the timing with which the digital data D22 in the second row and second column is selected by the input/output selecting circuit 30, and the selected digital data D22 in the second row and second column is outputted to the summer 42 provided in the second column. In the summer 42, the digital data D22 outputted later is added to the digital data D21.

Timing t11

This is the timing with which the summation result data

(D11+D12) and the summation result data (D21+D22) are outputted from the summers 42 by the scan performed by the column scanning circuit 50.

In the description so far,
the digital data D11 corresponds to a selected-row digital signal (first selected column) in an odd-numbered row;
the digital data D12 corresponds to a selected-row digital signal (second selected column) in an odd-numbered row;
the digital data D21 corresponds to a selected-row digital signal (first selected column) in an even-numbered row;
the digital data D22 corresponds to a selected-row digital signal (second selected column) in an even-numbered row;
the summation result data (D11+D12) corresponds to an odd-numbered row summation digital signal (first selected column+second selected column); and
the summation result data (D21+D22) corresponds to an even-numbered row summation digital signal (first selected column+second selected column).

As described so far, according to the present preferred embodiment,
the array of column-by-column summers 42 is provided on the input side of the column scanning circuit 50, and
the input/output selecting circuit 30 is provided between the array of column-by-column summers 42 and the array of column-by-column AD converters 22.

in addition to the constitution described above, pixel summation is carried out on the input side of the column scanning circuit 50.

As a result, the following effects can be obtained: in improving the frame rate by effectively performing summation in the row and column directions,
it is unnecessary to increase the operation frequency of the column scanning circuit 50, and
it is unnecessary to increase the number of the column scanners.

In the description given so far, two pixels adjacent to each other in the same row are summed. However, two pixels randomly picked or three or more pixels can be summed by changing the repeating cycle of the input/output selecting circuit 30. Furthermore, by carrying out the summation in the subsequent row without resetting the column-by column summer 42, the pixels in more than two rows can be summed.

In the case where the column-by-column AD converters 22 according to the present preferred embodiment are configured to perform summation between rows as in the Patent Document 2, the number of the column-by-column summers 42 to be provided can be lessened.

### Preferred Embodiment 2

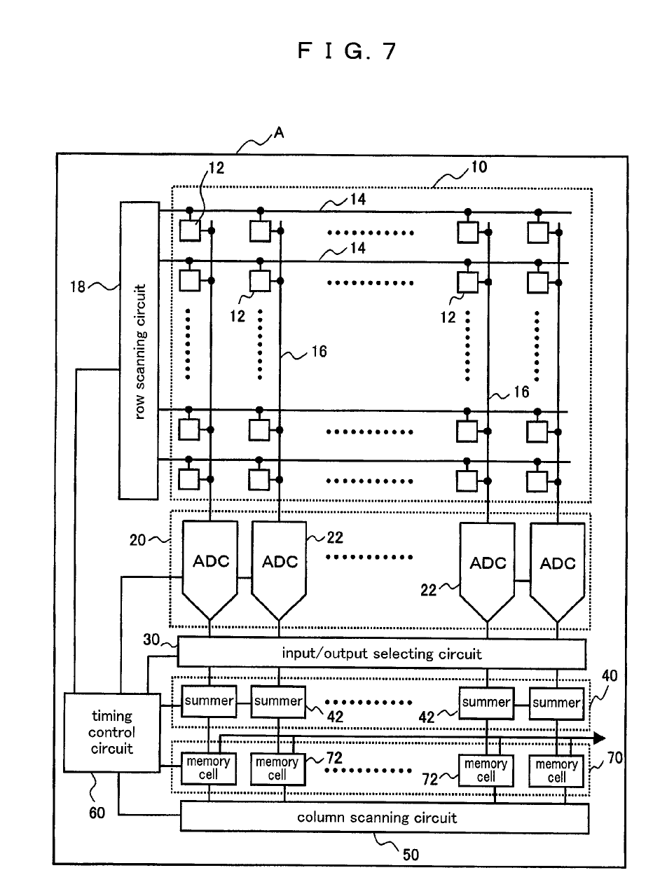

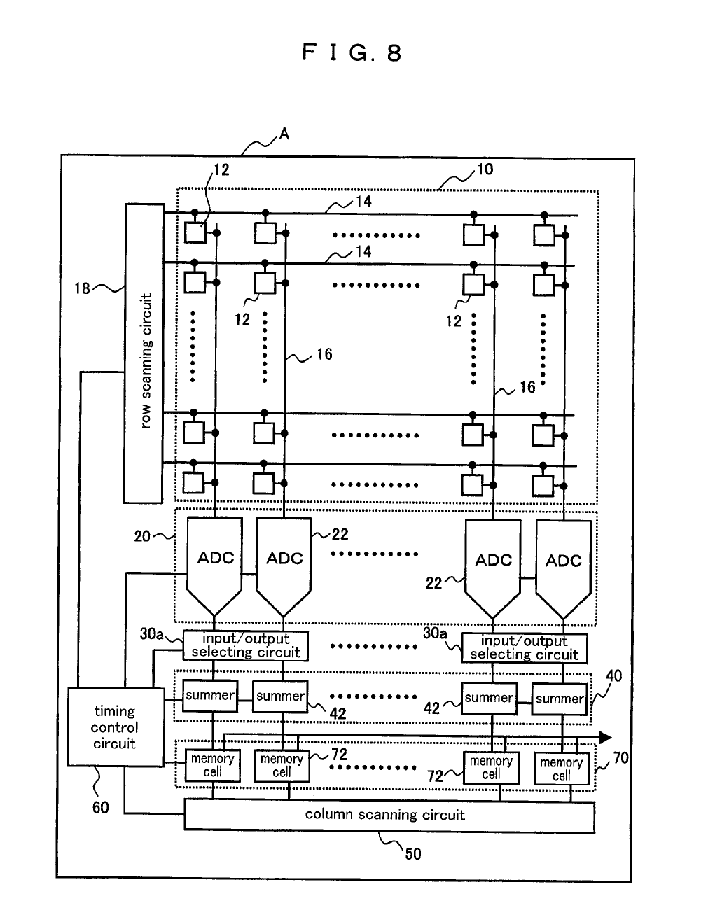

FIG. 7 is a block diagram illustrating a constitution of a solid-state image pickup device A according to a preferred embodiment 2 of the present invention. FIG. 8 corresponds to FIG. 2 according to the preferred embodiment 1. The present preferred embodiment is characterized in that a line memory 70 is further provided between a plurality of column-by-column summers 42 and a column scanning circuit 50 in the constitution according to the preferred embodiment 1. An array of column-by-column memory cells 72 for temporarily storing summation results of the column-by-column summers 42 constitutes the line memory 70. According to the constitution, since the data already subjected to the summation can be written in the memory cells 72, the data stored in the memory cells 72 can be outputted through the scan by the column scanning circuit 50, and, at the same time, the next AD conversion and summation can be started.

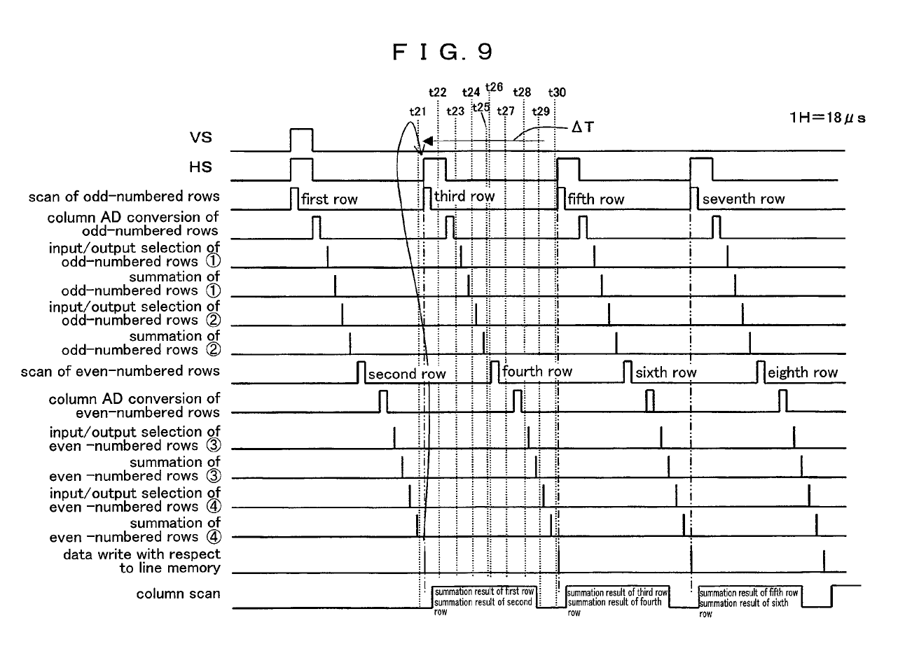

FIG. 9 is a timing chart illustrating an operation of the solid-state image pickup device A according to the present preferred embodiment. In the present preferred embodiment, data write with respect to the line memory is further provided in the constitution according to the preferred embodiment 1.

According to the constitution, since the line memory 70 is provided between the column-by-column summers 42 and the column scanning circuit 50, only if one cycle of the summation processing is completed with regard to two pixel rows to be summed in all of the column-by-column summers 42, the row selection for a subsequent cycle can be started by the row scanning circuit 18. This means that it is unnecessary to wait for the cycle of the column scan by the column scanning circuit 50 to be completed before starting the row selection for the next cycle by the row scanning circuit 18. Therefore, right after the data storage into the line memory 70 is completed with regard to all of the column-by-column summers 42 and immediately before or after the cycle of the column scan is started, the row selection for the next cycle can be started, and then the column-by-column AD conversion, input/output selection and column-by-column summation can be performed.

It was recited by way of example in the preferred embodiment 1 that “the summation data in the third row and the fourth row are processed when the output of all of the summation data in the first row and the second row is completed” as marked with *1 (see FIG. 3) in the description. In other words, the constitution according to the preferred embodiment 1 is subject to restrictions under which the processing of the third and fourth rows cannot be started before the column scan of the summation result in the first row and the summation result in the second row is completed. This is because the summation results need to be retained in the column-by-column summers 42 until the column scan is completed. In contrast to the preferred embodiment 1, in the present preferred embodiment, since the line memory 70 for retaining the summation results is additionally provided, the next row may be processed as soon as the summation results are retained in the line memory 70 even before the column scan is completed.

As described so far, according to the present preferred embodiment, the first processing (column scan and column-by-column AD conversion), the second processing (input/output selection), and the third processing (column-by-column summation) can be concurrently carried out. As a result, the frame rate can be further improved, and the operation can attain a higher speed. For example, a horizontal period (1H) according to the preferred embodiment 1 is 34 μs, while the same is reduced in the present embodiment to 18 μs, or about 58%.

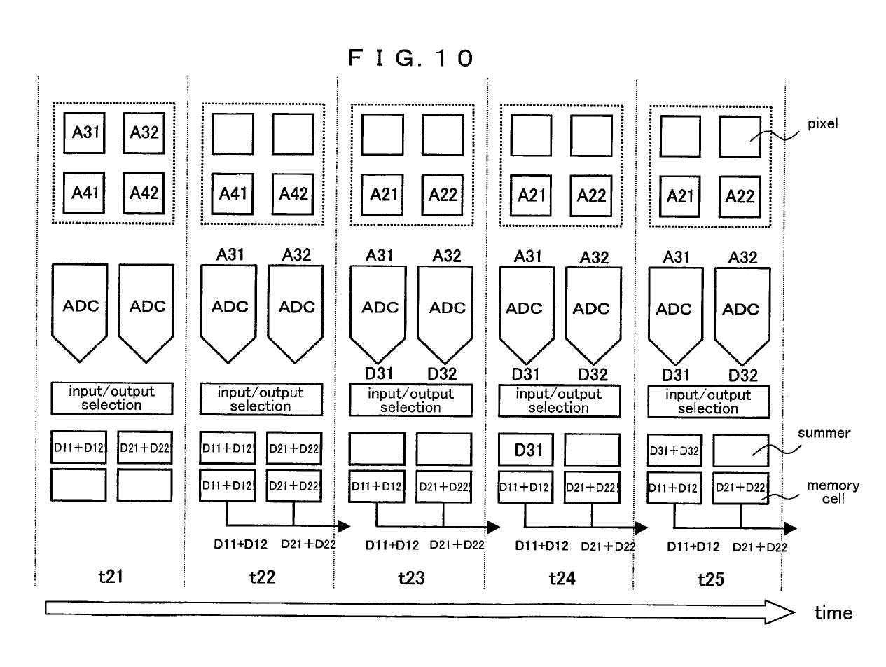

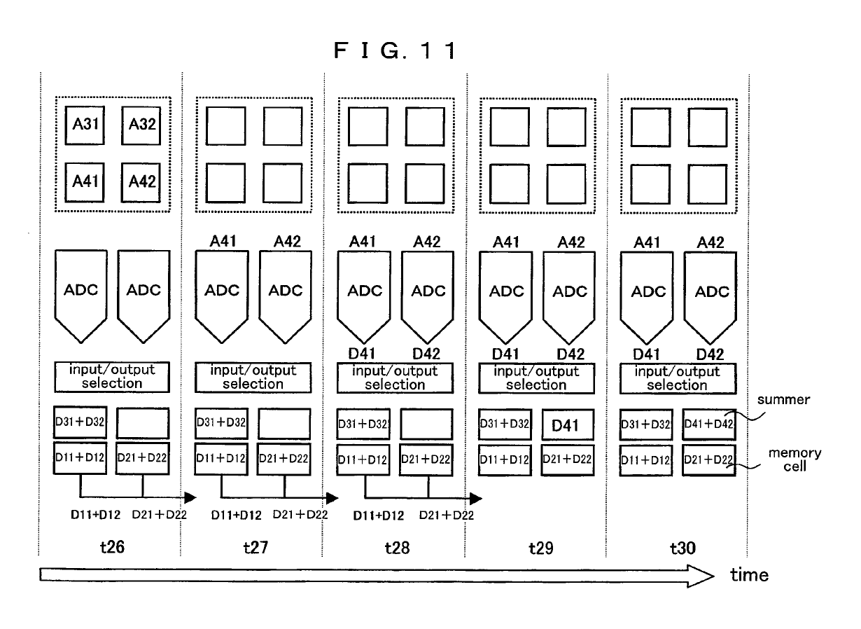

Next, the operation according to the present preferred embodiment is described referring to the operation transition charts illustrated in FIGS. 10 and 11. The reference symbols t21-t25 illustrated in FIG. 10 and t26-t30 illustrated in FIG. 11 denote serial numbers of timing. The description given below referring to FIGS. 10 and 11 recites the operation for 2×2 pixels alone to facilitate the understanding.

In FIGS. 10 and 11, A 31 denotes analog data of a pixel in the third row and first column, A32 denotes analog data of a pixel in the third row and second column, A41 denotes analog data of a pixel in the fourth row and first column, and A42 denotes analog data of a pixel in the fourth row and second column. D31 denotes digital data obtained by AD-converting the analog signal A31, D32 denotes digital data obtained by AD-converting the analog signal A32, D41 denotes digital data obtained by AD-converting the analog signal A41, and D42 denotes digital data obtained by AD-converting the analog signal A42.

Timing t21

This is the timing with which charges, which represent a photoelectric conversion result of a photographic subject, are stored in the group of the unit pixels 12, and result in the analog data A31, A32, A41 and A42. However, this is also the timing with which the summation for the first and second row has already been completed as in the preferred embodiment 1, and the summation result data (D11+D12) and (D21+D22) of the first and second rows are already retained in the summers 42.

Timing t22

This is the timing with which the following operations are concurrently executed:
the analog data A31 and A32 of the third row are inputted to the AD converters 22;
the summation result data (D11+D12) of the first row and the summation result data (D21+D22) of the second row in the summers 42 are written in the memory cells 72; and
the summation result data (D11+D12) and (D21+D22) are outputted from the memory cells 72 by the column scanning circuit 50.

Timing t23

This is the timing with which the AD conversion is completed, and the digital data D31 and D32 are outputted. At the same time, the summation result data (D11+D12) and (D21+D22) of the memory cells 72 are scanned.

Timing t24

This is the timing with which the digital data D31 in the third row and first column is selected by the input/output selecting circuit, and the selected digital data D31 in the third row and first column is then outputted to the summer 42 provided in the first column.

Timing t25

This is the timing with which the digital D32 in the third row and second column is selected by the input/output selecting circuit 31, and the selected digital data D32 in the third row and second column is also outputted to the summer 42 provided in the first column. In the summer 42, the digital data D32 outputted later is added to the digital data D31, so that a summation result data (D31+D32) is generated.

Timing t26

This is the timing with which the data of the AD converters 22 is reset.

Timing t27

This is the timing with which the analog data A41 and A42 in the fourth row are inputted to the AD converters 22.

Timing t28

This is the timing with which the AD conversion is completed, and the digital data D41 and D42 are outputted from the AD converters 22.

Timing t29

This is the timing with which the digital D41 in the fourth row and first column is selected by the input/output selecting circuit 30, and the selected digital data D41 in the fourth row and first column is then outputted to the summer 42 provided in the second column. At the time, the output of the data in the memory has already been completed by the column scan.

Timing t30

This is the timing with which the digital D42 in the fourth row and second column is selected by the input/output selecting circuit 30, and the selected digital data D42 in the fourth row and second column is also outputted to the summer 42 provided in the second column. In the summer 42, the digital data D42 outputted later is added to the digital data D41, so that summation result data (D41+D42) is generated.

In the description given so far:
the digital data D11 and D31 correspond to selected-row digital signals (first selected column) in an odd-numbered row;
the digital data D12 and D32 correspond to selected-row digital signals (second selected column) in an odd-numbered row;
the digital data D21 and D41 correspond to selected-row digital signals (first selected column) in an even-numbered row;
the digital data D22 and D42 correspond to selected-row digital signals (second selected column) in an even-numbered row;
the summation result data (D11+D12) and (D31+D32) correspond to odd-numbered row summation digital signals (first selected column+second selected column); and
the summation result data (D21+D22) and (D41+D42) correspond to even-numbered row summation digital signals (first selected column+second selected column).

By repeating the operations described so far, an image is outputted. The present preferred embodiment is different to the preferred embodiment 1 in that the output of the memory data by the column scan can be carried out concurrently with AD conversion, summation and other processes.

### Preferred Embodiment 3

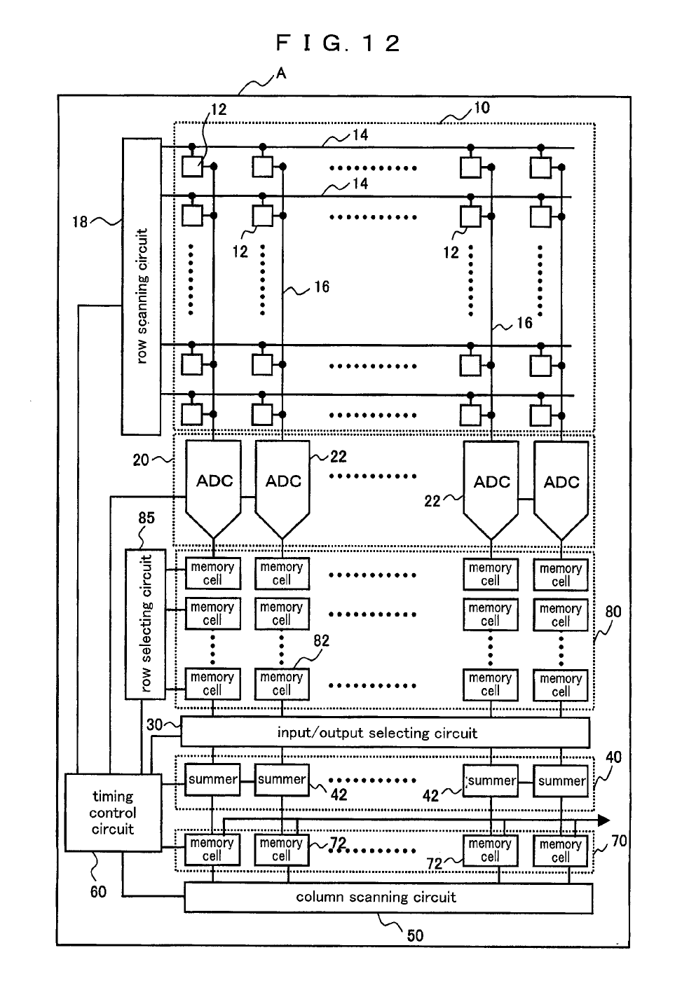

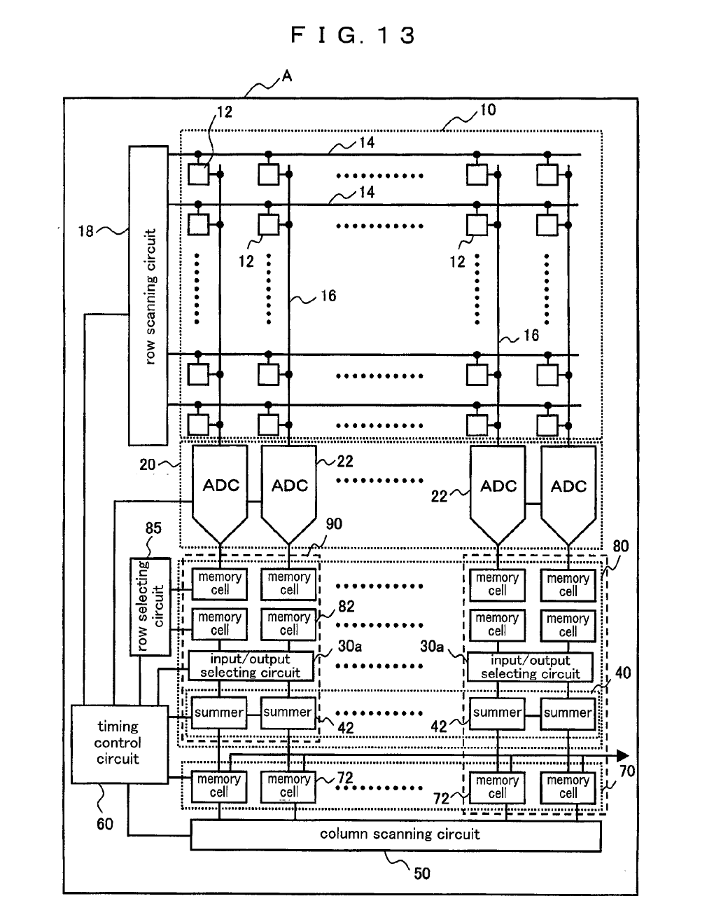

FIG. 12 is a block diagram illustrating a constitution of a solid-state image pickup device A according to a preferred embodiment 3 of the present invention. FIG. 13 corresponds to FIG. 8 of the preferred embodiment 2. The present preferred embodiment is characterized in that a memory cell array unit 80 and a memory row selecting circuit 85 are further provided in the constitution according to the preferred embodiment 2.

The memory cell array unit 80 is provided between a plurality of column-by-column AD converters 22 and an input/output selecting circuit 30. An array of memory cells 82 provided in a plurality of rows constitutes the memory cell array unit 80. The memory cell array unit 80 can write the data outputted from the column-by-column AD converters 22 on a row-by-row basis and can read the data with respect to the column-by-column summers 42 on a row-by-row basis. The memory row selecting circuit 85 selects rows in the memory cell array unit 80 to thereby control the data write and read with respect to the memory cell array unit 80.

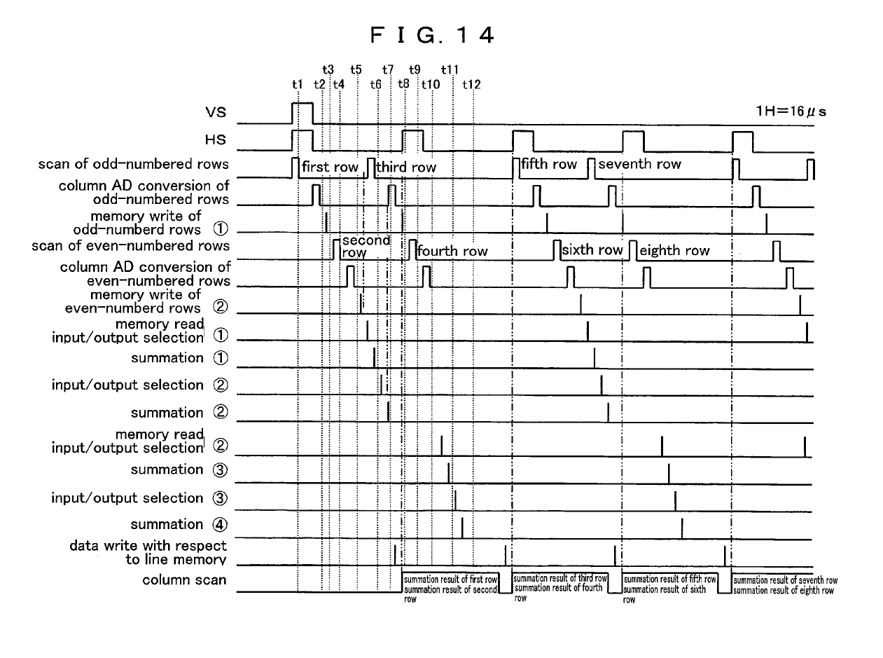

The number of the memory cells 82 in the column direction is equal to the number of the unit pixels 12 and the number of the AD converters 22, each in the column direction. The number of the memory cells 82 in the row direction is equal to the number of the rows to be signal-processed. In the constitution illustrated in FIG. 13, the memory cells 82 are provided in two rows because the number of the rows to be signal-processed is two. In the memory cell array unit 80, a row from which the data is read and a row in which the data is written can be independently selected, and the data can be selectively written and read with respect to different rows at the same time. In FIG. 14 illustrating an operation timing chart, timings of writing and reading the data with respect to the memory for two rows are additionally illustrated. Accordingly, the AD conversion, input/output selection and the summation can be carried out at the same time, and the data can be thereby output at a high speed.

An operation of the solid-state image pickup device according to the present preferred embodiment thus constituted is described below. As described earlier, it is important to read the description given below while carefully paying attention to a distinction between “odd-numbered row,” “even-numbered row,” “odd-numbered column” and “even-numbered column.”

In the scan of the odd-numbered rows in the pixel array unit 10, the group of unit pixels 12 in the first row are selected. Next, in the column AD conversion based on the scan of the odd-numbered rows, analog signals outputted from all of the unit pixels 12 in the first row are AD-converted into digital signals. Then, in a memory writing process (1), the digital signals obtained by the column-by-column AD conversion are temporarily stored in the memory cells 82 in the first row in the memory cell array unit 80, and the even-numbered rows are then scanned.

In the scan of the even-numbered rows, the group of unit pixels 12 in the second row are selected. Next, in the column AD conversion based on the scan of the even-numbered rows, analog signals outputted from all of the unit pixels 12 in the second row are AD-converted into digital signals. Then, in a memory writing process (2), the digital signals obtained by the column-by-column AD conversion are temporarily stored in the memory cells 82 in the second row in the memory cell array unit 80.

Next, the group of the memory cells 82 in the first row in the memory cell array unit 80 are selected by the memory row selecting circuit 85. Further, the memory cells 82 in the odd-numbered column and the summer 42 in the odd-numbered column are selected by the input/output selecting circuit 30a, and the first data in the column direction is retained for pixel summation.

Then, the memory cells 82 in the even-numbered column and the summer 42 in the odd-numbered column are selected by the input/output selecting circuit 30a, and the second data in the column direction is added to the first data.

Subsequent to the completion of the foregoing processes, the selected row in the memory cell array unit 80 is changed; namely, the group of the memory cells 82 in the second row in the memory cell array unit 80 is selected by the memory row selecting circuit 85. Furthermore, the memory cells 82 in the odd-numbered column and the summer 42 in the odd-numbered column are selected by the input/output selecting circuit 30a, and the first data in the column direction is retained for pixel summation. Then, the memory cells 82 in the even-numbered column and the summer 42 in the odd-numbered column are selected by the input/output selecting circuit 30a, and the second data in the column direction is added to the first data.

As a result of the processing described so far, all of the column-by-column summers 42 are in a state illustrated in FIG. 6C. More specifically, composite pixel summation data in which the intra-row pixel summation data are incorporated between two rows is obtained in all of the column-by-column summers 42. Then, the composite pixel summation data is transferred to the line memory 70 as in the preferred embodiment 2. The memory cells 72 of the line memory 70 has been subjected to column scan by the column scanning circuit 50, and the composite pixel summation data stored in the line memory 70 are serially outputted to the outside.

The present preferred embodiment is compared to the preferred embodiment 2 as below. In the preferred embodiment 2 (FIG. 9), the third row can be selected only if the following conditions are met:
the pixel summation in the first row and the pixel summation in the second row are completed; and
the transfer of the pixel summation data in the first row and the pixel summation data in the second row to the line memory 70 is completed.

According to the present preferred embodiment, the third row can be selected provided that,
the transfer of the pixel data in the first row to the memory cells 82 and the transfer of the pixel data in the second row to the memory cells 82 are completed.

Thus, the requirements of the present preferred embodiment are less than those in the preferred embodiment 2.

In the present preferred embodiment, since the memory cell array unit 80 is provided, it is not necessary for the data transfer from the summers 42 to the line memory 70 to be completed before the third row is selected. Further, unlike the preferred embodiment 2, the AD conversion of the image signals in the third row can be started when the memory cells 82 are read to be updated after the summations for the first and second rows in the summers 42 are completed.

As described so far, according to the present preferred embodiment, since the memory cell array unit 80 is provided between the plurality of the AD converters 22 and the input/output selecting circuit 30a, the row selection for the next cycle can be started by the row scanning circuit 18 as soon as one cycle of the AD conversion of all the pixels by the AD converters 22 is completed in all of the pixels in two rows subject to the summation. In other words, it is unnecessary for the row scanning circuit 18 to wait for the cycles of the input/output selection and column-by-column summation to be completed before starting the row selection for the next cycle.

Therefore, according to the present preferred embodiment, the row selection for the next cycle can be started to perform AD conversion immediately before or after the cycles of the input/output selection and the column-by-column summation are started right after the AD conversion for all of the pixels is completed. Accordingly, the input/output selection and the column-by-column summation, and the AD conversion can be concurrently carried out, which further improves the frame rate. For example, the horizontal period (1H) according to the preferred embodiment 1 is 34 μs, while the same according to the present embodiment is reduced to 16 μs, or 47%.

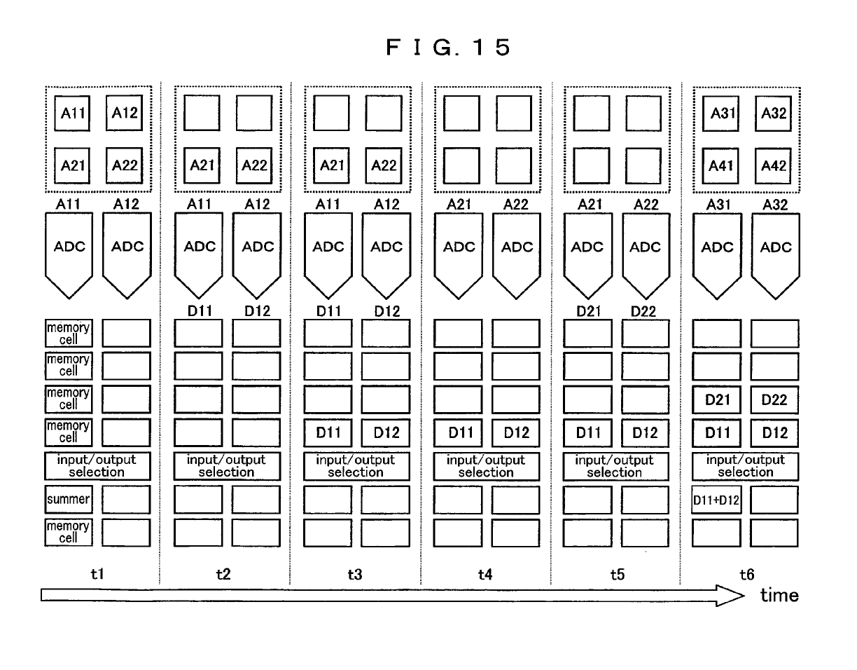

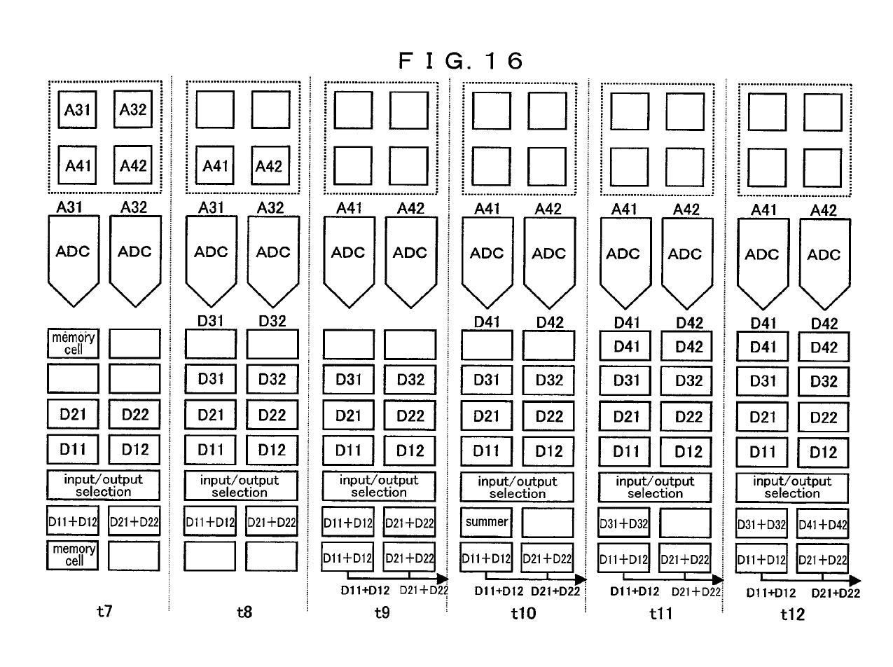

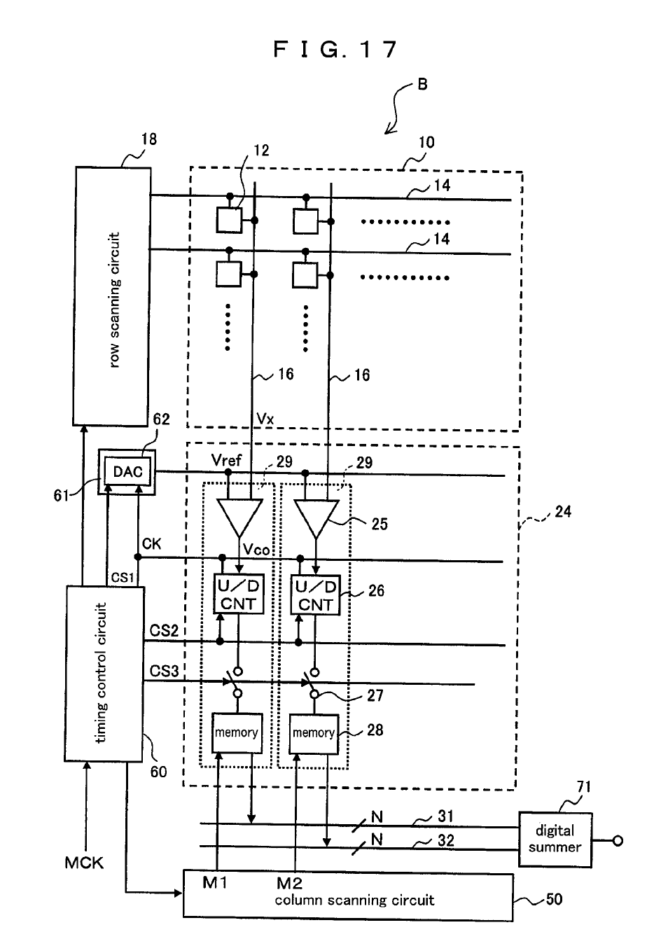

Next, the operation according to the present preferred embodiment is described referring to operation transition charts illustrated in FIGS. 15 and 16. The reference symbols t1-t6 and t7-t21 illustrated in FIGS. 15 and 16 respectively denote serial numbers oe timing. The description given below referring to FIGS. 10 and 11 recites the operation for 2×2 pixels alone to facilitate the understanding. In the description given below referring to FIGS. 15 and 16, 2×2 pixels alone are recited, while pixels in the third and fourth rows are recited from Timing t6 onward.

Timing t1

This is the timing with which analog data A11 and A12 in the first row are inputted to the AD converters 22.

Timing t2

This is the timing with which the AD conversion of the analog data A11 and A12 in the first row is completed, and digital data D11 and D12 are outputted from the AD converters 22.

Timing t3

This is the timing with which the digital data D11 and D12 in the first row are written in the memory cells 82.

Timing t4

This is the timing with which analog data A21 and A22 in the second row are supplied to the AD converters 22.

Timing t5

This is the timing with which the AD conversion of the analog data A21 and A22 in the second row is completed, and digital data D21 and D22 are outputted from the AD converters 22.

Timing t6

This is the timing with which the digital data D21 and D22 in the second row are written in the memory cells 82, and at the same time, the digital data D11 and digital data D12 in the first row are selected by the input/output selecting circuit 30 and the selected digital data D11 and digital data D12 are summed in the summer 42 provided in the first column, and consequently summation result data (D1+D12) is generated. At the same time, analog data A31 and A32 in the third row are inputted to the AD converters 22. In this description, the summation is described in a simplified manner as a series of the operations; however, the summation is actually carried out as in the preferred embodiments 1 and 2.

Timing t7

This is the timing with which the digital data D21 and the digital data in the second row are selected by the input/output selecting circuit 30, and the selected digital data D21 and digital data D22 are summed in the summer 42 provided in the second column. As a result, summation result data (D21+D22) is generated.

Timing t8

This is the timing with which the AD conversion of the analog data A31 and A32 in the third row is completed by the AD converters 22, and the digital data D11 and D12 are outputted from the AD converters 22 and written in the memory cells 82.

Timing t9

This is the timing with which analog data A41 and A42 in the fourth row are read, and at the same time the summation result data (D11+D12) of the first row and the summation result data (D21+D22) of the second row in the summers 42 are written in the memory cells 72 and then outputted from the memory cells 72 by the column scanning circuit 50.

Timing t10

This is the timing with which the AD conversion of the analog data A41 and A42 in the fourth row is completed by the AD converters 22, and digital data D41 and D42 are outputted from the AD converters 22. At that time, the summation result data (D11+D12) and (D21+D22) of the first and second rows are continuously outputted from the memory cells 72 by the column scanning circuit 50.

Timing t11

This is the timing with which the digital data D41 and D42 in the fourth row are outputted from the AD converters 22 and written in the memory cells 82, and at the same time the digital data D31 and digital data D32 of the third row written in the memory cells 82 are summed, and consequently summation result data (D31, D32) is generated. At that time, the summation result data (D11+D12) and (D21+D22) of the first and second rows are continuously outputted from the memory cells 72 by the column scanning circuit 50.

Timing t12

This is the timing with which the digital data D41 and the digital data D42 of the fourth row written in the memory cells 82 are summed, so that a summation result data (D41+D42) is generated. At that time, the summation result data (D11+D12) and (D21+D22) of the first and second rows are continuously outputted from the memory cells 72 by the column scanning circuit 50.

When the operation thus far described is repeated, an image is outputted. The present preferred embodiment is different to the preferred embodiment 2 in that the AD conversion and the summation can be concurrently carried out. As a result, the image can be more speedily outputted.

In the present preferred embodiment, the summation of two adjacent pixels in the horizontal direction was simply described. However, any pixels randomly picked or three or more pixels may be summed when the repetitive cycle of the input/output selecting circuit 30 is increased. Furthermore, in the case where the column-by-column summers 42 are not reset for a different row and the summation is continuously carried out, the pixels in an arbitrary row in the vertical direction can be summed. Therefore, signals of the same color of a color filter having a two-dimensional repeating cycle such as the Bayer array can be summed based on a predetermined two-dimensionally repetitive cycle.

Further, when the repetitive cycle and the driving method of the input/output selecting circuit 30 are suitably set, a plurality of summation modes can be selectively adopted.

### INDUSTRIAL APPLICABILITY

The solid-state image pickup device and the method of driving the same according to the present invention are useful because a frame rate and sensitivity can be improved when pixels are summed in horizontal and vertical directions on a column-by-column basis.

What is claimed is:

1. A solid-state image pickup device comprising:
a pixel array unit in which unit pixels including photoelectric conversion elements are two-dimensionally disposed in a matrix array;
a row scanner for selectively controlling the unit pixels of the pixel array unit on a row-by-row basis;
column-by-column AD converters provided in columns of the pixel array unit on a column-by-column basis for converting an analog signal of each pixel in the row selected by the row scanner into a digital signal;
column-by-column summers provided in the columns on a column-by-column basis for summing the digital signal of each pixel in the row selected by the row scanner on a column-by-column basis;
an input/output selector provided between the column-by-column AD converters and the column-by-column summers, the input/output selector selecting the column-by-column AD converter in any arbitrary column as an input destination and further selecting the column-by-column summer in any arbitrary column as an output destination;
a column scanner for serially outputting summation results of the column-by-column summers by scanning columns; and
a controller for controlling the timing of the operations of the row scanner, the column-by-column AD converters, the input/output selector and the column-by-column summers.

2. The solid-state image pickup device as claimed in claim 1, further comprising a line memory for temporarily storing the summation results of the column-by-column summers between the plurality of the column-by-column summers and the column scanner.

3. The solid-state image pickup device as claimed in claim 2, further comprising:
a memory cell array unit in which output data of the column-by-column AD converters for a plurality of rows can be written on a row-by-row basis and from which the data can be read with respect to the column-by-column summers on a row-by-row basis; and
a memory row selector for controlling the data write and the data read of the memory cell array unit by selecting rows.

4. A method of driving a solid-state image pickup device comprising:
a first step in which a selected row is set in a pixel array unit in which unit pixels including photoelectric conversion elements are two-dimensionally disposed in a matrix array, and analog signals of the unit pixels in each column of the selected row are AD-converted so as to generate a group of selected-row digital signals;
a second step in which a first selected column is set in the pixel array unit, and the selected-row digital signal in the first selected column (first selected column) is retrieved from the group of selected-row digital signals and retained;
a third step in which a second selected column is set in the pixel array unit, and the selected-row digital signal in the second selected column (second selected column) is retrieved from the group of selected-row digital signals and added to the selected-row digital signal (first selected column) so as to generate a summation digital signal (first selected column+second selected column);
a fourth step in which the first-third steps are carried out by changing the selected row so as to serially generate a group of the summation digital signals for a plurality of rows (first selected column+second selected column); and
a fifth step in which the summation digital signals (first selected column+second selected column) constituting the group of the summation digital signals of the plurality of rows (first selected column+second selected column) are serially outputted by column scanning.

5. The method of driving a solid-state image pickup device as claimed in claim 4, further comprising a sixth step in which the group of the summation digital signals (first selected column+second selected column) are temporarily stored, between the fourth step and the fifth step.

6. The method of driving a solid-state image pickup device as claimed in claim 4, further comprising:
a seventh step and an eighth step between the first step and the second step, wherein
in the seventh step, the group of selected-row digital signals generated in the first step are retained;
in the eighth step, the first and seventh steps are carried out by changing the selected row and a group of the selected-row digital signals for a plurality of rows are thereby generated and retained, and
in the second step, a group of selected-row digital signals of any arbitrary row is read from among the group of selected-row digital signals for the plurality of rows retained in the eighth step and used.
